(19) United States
(12) Patent Application Publication
(10) Pub. No.: US 2026/0231639 A1
(43) Pub. Date: Aug. 6, 2026

(54) DISPLAY DEVICE

(71) Applicant: Sharp Display Technology Corporation, Kameyama City, Mie (JP)

(72) Inventors: Junichi YAMADA, Kameyama City (JP); Yasushi KUBOTA, Kameyama City (JP)

(21) Appl. No.: 19/152,468

(22) PCT Filed: Feb. 2, 2023
(86) PCT No.: PCT/JP2023/003360

§ 371 Date: Jul. 31, 2025

(51) Int. Cl. H10K 59/131

(52) U.S. Cl. CPC H10K 59/1315

(57) ABSTRACT

A display device includes: a display area including a subpixel; and a frame area surrounding the display area, wherein the frame area includes: a terminal section including a plurality of terminals; a bending portion located between the terminal section and the display area; a line-break-detection wiring line having an end connected electrically to a first terminal of a terminal group of the terminal section and another end connected electrically to a second terminal of a terminal group of the terminal section; and a plurality of display wiring lines, the line-break-detection wiring line is shaped so as to cross over the bending portion at a plurality of sites, and at least one of the plurality of sites is located between two of the plurality of display wiring lines crossing over the bending portion

### TECHNICAL FIELD

The present disclosure relates to display devices.

### BACKGROUND ART

In the field of display devices, technology is being developed to detect wiring defects in the inspection stage before the product is shipped out, with a view to provide a display device with improved reliability.

For instance, Patent Literature 1 describes a method of manufacturing an organic EL display panel that allows for detection of defects in data wiring lines for selection transistors included in pixel circuits in the display area of the organic EL display panel.

### CITATION LIST

### Patent Literature

Patent Literature 1: Japanese Unexamined Patent Application Publication No. 2016-80822

### SUMMARY

### Technical Problem

However, according to the manufacturing method described in Patent Literature 1, to detect defects in the data wiring lines for selection transistors included in pixel circuits in the display area, scan lines connected electrically to data wiring lines in the display area and a common inspection line are further provided in the non-display area which is the frame area of the organic EL display panel, and after the inspection, a portion of the substrate where the scan lines and the common inspection line are provided is either entirely cut out or electrically disconnected by providing a diode between the common inspection line and the scan lines.

As described in the foregoing, the method of manufacturing an organic EL display panel described in Patent Literature 1 involves, after the inspection, either a cutting step or a diode provision step, both of which might cause new defects in the data wiring lines, and this would lead to a failure in providing an organic EL display panel with improved reliability.

Meanwhile, active development has been under way for a display device that includes a bending portion in the non-display area which is the frame area to allow for reduced frame dimensions by bending this bending portion. The bending portion includes a plurality of display wiring lines crossing over the bending portion, and when the bending portion is bent, might develop wiring line defects such as breaks in the plurality of display wiring lines. The manufacturing method described in Patent Literature 1 detects defects in data wiring lines provided in the display area and for this reason, is not applicable to the detection of defects in the plurality of display wiring lines crossing over the bending portion in the non-display area which is the frame area.

The present disclosure, in an aspect thereof, has been made in view of these problems and has an object to provide a display device with improved reliability that allows for detection of a defect in a plurality of display wiring lines crossing over a bending portion provided in the non-display area which is the frame area.

### Solution to Problem

A display device in accordance with the present disclosure, to address the problems, includes: a display area including a subpixel; and a frame area surrounding the display area, wherein
the frame area includes: a terminal section including a plurality of terminals; a bending portion located between the terminal section and the display area; a line-break-detection wiring line having an end connected electrically to a first terminal of the terminal section and another end connected electrically to a second terminal of the terminal section; and a plurality of display wiring lines,
the line-break-detection wiring line is shaped so as to cross over the bending portion at a plurality of sites, and
at least one of the plurality of sites is located between two of the plurality of display wiring lines crossing over the bending portion.

### Advantageous Effects of Disclosure

The present disclosure, in an aspect thereof, can provide a display device with improved reliability that allows for detection of a defect in a plurality of display wiring lines crossing over a bending portion provided in the non-display area which is the frame area.

### BRIEF DESCRIPTION OF DRAWINGS

FIG. 1 is a schematic plan view of a structure of a display device in accordance with Embodiment 1.

FIG. 2 is a schematic cross-sectional view of the structure of the display device in accordance with Embodiment 1, taken along line A-A′ shown in FIG. 1.

FIG. 3 is a diagram illustrating a method of detecting a defect in a plurality of display wiring lines crossing over a bending portion of the display device in accordance with Embodiment 1.

FIG. 4 is a diagram of each layer provided on a substrate of the display device in accordance with Embodiment 1.

FIG. 5 is a circuit diagram of an example of a pixel circuit included in a display area of the display device in accordance with Embodiment 1.

FIG. 6 is a schematic cross-sectional view of the structure of the display device in accordance with Embodiment 1, taken along line B-B′ shown in FIG. 3.

FIG. 7 is a schematic cross-sectional view of the structure of the display device in accordance with Embodiment 1, taken along line C-C′ shown in FIG. 3.

FIG. 8 is a schematic cross-sectional view of the structure of the display device in accordance with Embodiment 1, taken along line D-D′ shown in FIG. 3.

FIG. 9 is a schematic cross-sectional view of the structure of the display device in accordance with Embodiment 1, taken along line E-E′ shown in FIG. 3.

FIG. 10 is a diagram showing an example of a line-break-detection method using a peripheral-crack-detection wiring line and a line-break-detection wiring line provided in the display device in accordance with Embodiment 1.

FIG. 11 is a diagram showing an example of a method of categorizing display devices into non-defective products, undetermined products, and defective products based on the conduction state and the resistance values obtained by the line-break-detection method shown in FIG. 10.

FIG. 12 is a schematic plan view of a structure of another display device in accordance with Embodiment 1.

FIG. 13 is a schematic plan view of a structure of yet another display device in accordance with Embodiment 1.

FIG. 14 is a diagram showing another example of a line-break-detection method using a peripheral-crack-detection wiring line and a line-break-detection wiring line provided in the display device in accordance with Embodiment 1.

FIG. 15 is a diagram showing an example of a method of categorizing display devices into non-defective products, undetermined products, and defective products based on the conduction state and the resistance values obtained by the line-break-detection method shown in FIG. 14.

FIG. 16 is a schematic plan view of a structure of a display device in accordance with Embodiment 2.

FIG. 17 is a schematic plan view of a structure of a display device in accordance with Embodiment 3.

FIG. 18 is a schematic plan view of a structure of a display device in accordance with Embodiment 4.

FIG. 19 is a schematic plan view of a structure of a display device in accordance with Embodiment 5.

### DESCRIPTION OF EMBODIMENTS

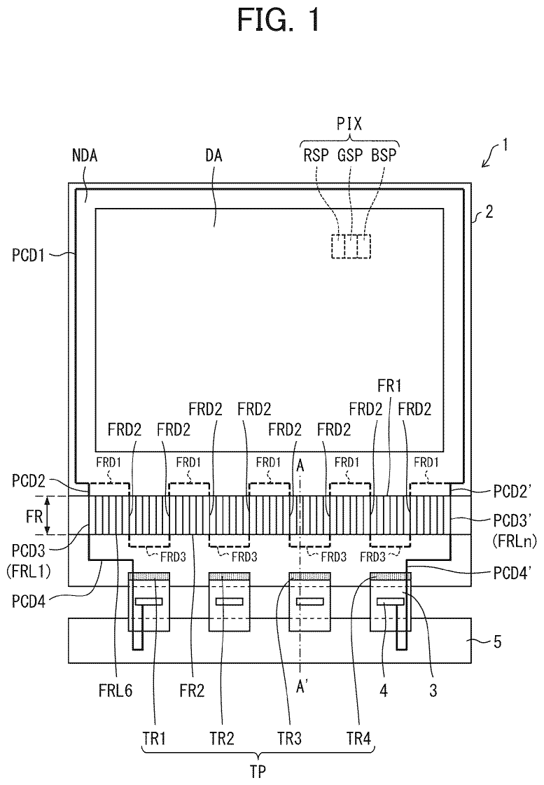

The following will describe embodiments of the present invention with reference to FIGS. 1 to 19. Throughout the following, members of an embodiment that have the same arrangement and function as members of a specific embodiment are denoted by the same reference numerals and description thereof may be omitted for convenience of description.

### Embodiment 1

FIG. 1 is a schematic plan view of a structure of a display device 1 in accordance with Embodiment 1.

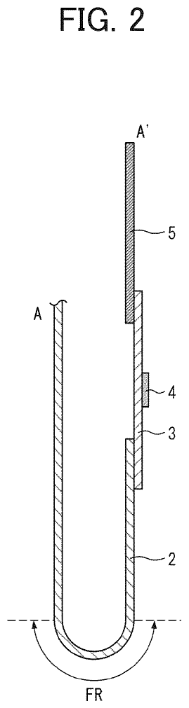

FIG. 2 is a schematic cross-sectional view of the structure of the display device 1 in accordance with Embodiment 1, taken along line A-A′ shown in FIG. 1.

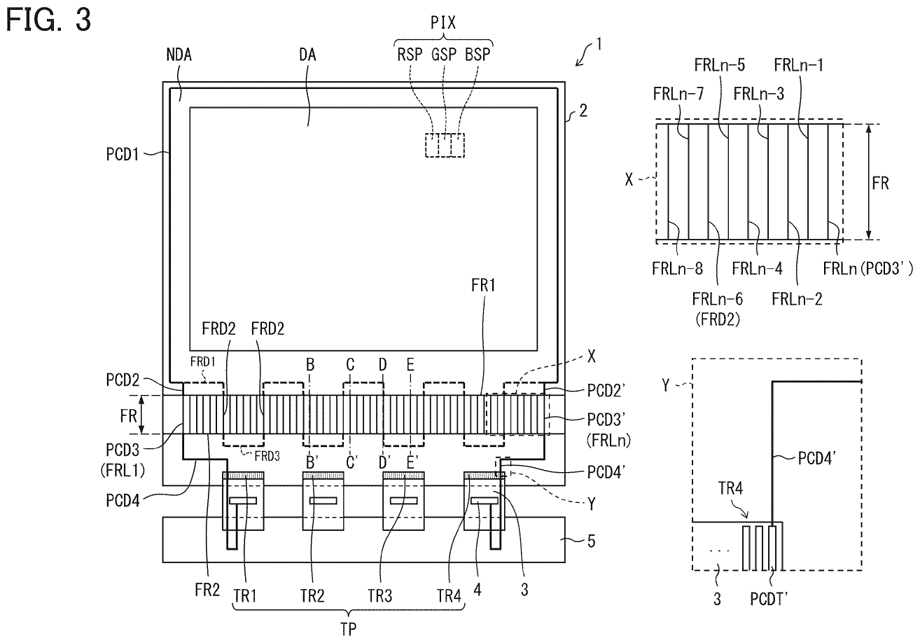

FIG. 3 is a diagram illustrating a method of detecting a defect in a plurality of display wiring lines crossing over a bending portion FR of the display device 1 in accordance with Embodiment 1.

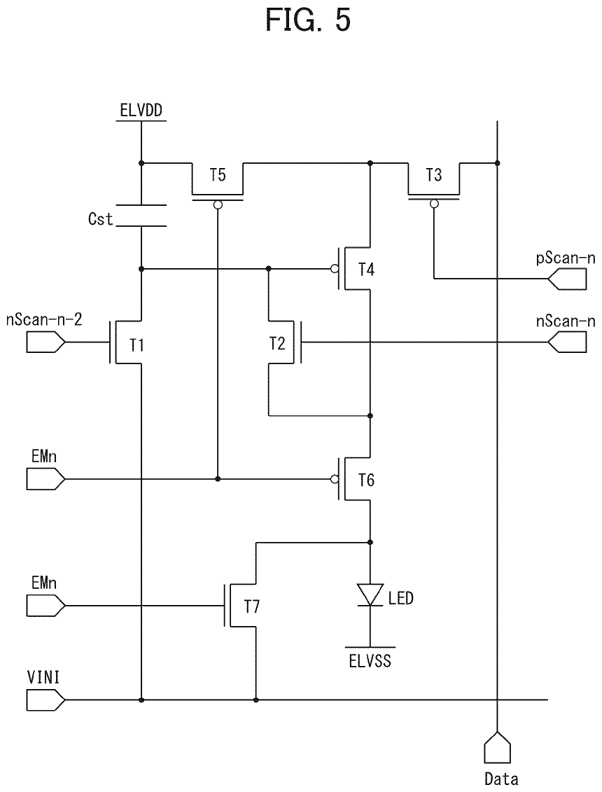

FIG. 5 is a circuit diagram of an example of a pixel circuit included in a display area DA of the display device 1 in accordance with Embodiment 1.

Referring to FIG. 1, the display device 1 includes, on a substrate 2: the display area DA; and a frame area NDA that is a non-display area surrounding the display area DA.

The substrate 2 needs only to be a flexible substrate and is, as an example, a resin substrate composed of polyimide and/or another resin material(s) for illustrative purposes in the present embodiment. This is however not the only possible implementation of the invention.

The display area DA of the display device 1 includes therein a plurality of pixels PIX including red subpixels RSP, green subpixels GSP, and blue subpixels BSP. The present embodiment describes, as an example, each pixel PIX as including one the red subpixels RSP, one of the green subpixels GSP, and one of the blue subpixels BSP, which is merely illustrative. Alternatively, each pixel PIX may include a subpixel of another color apart from the red subpixel RSP, the green subpixel GSP, and the blue subpixel BSP.

The pixel circuit shown in FIG. 5 (not shown in FIGS. 1 and 3) is included correspondingly to each of the red subpixels RSP, the green subpixels GSP, and the blue subpixels BSP in the display area DA of the display device 1. The red subpixel RSP includes a pixel circuit including a red-light-emitting element as the light-emitting element LED shown in FIG. 5, the green subpixel GSP includes a pixel circuit including a green-light-emitting element as the light-emitting element LED shown in FIG. 5, and the blue subpixel BSP includes a pixel circuit including a blue-light-emitting element as the light-emitting element LED shown in FIG. 5.

The present embodiment describes, as an example, each light-emitting element LED as being an OLED (organic light-emitting diode) including an organic light-emitting layer, which is merely illustrative. Alternatively, the light-emitting element LED may be, for example, a QLED (quantum-dot light-emitting diode) including a light-emitting layer containing quantum dots.

The pixel circuit shown in FIG. 5 includes: one light-emitting element LED as the light-emitting element LED; seven transistors T1 to T7; and one retention capacitor Cst. The transistor T1 is a first initialization transistor, the transistor T2 is a threshold-compensation transistor, the transistor T3 is a write control transistor, the transistor T4 is a drive transistor, the transistor T5 is a first light-emission control transistor, the transistor T6 is a second light-emission control transistor, and the transistor T7 is a second initialization transistor.

The transistor T1, the transistor T2, and the transistor T7 are n-type transistors. On the other hand, the remaining transistors T3 to T6 are p-type transistors. Note that all the transistors except for the transistor T4 which is a drive transistor, that is, the transistors T1 to T3 and the transistors T5 to T7, function as a switching element.

Referring to FIG. 5, the transistor T1 has: a gate electrode thereof connected electrically to a second preceding, second scan signal line nScan-n-2 for a second scan signal input; a drain electrode thereof connected to one of two electrodes of the retention capacitor Cst, to the gate electrode of the transistor T4, and to the source electrode of the transistor T2; and a source electrode thereof connected electrically to an initialization voltage line VINI to which an initialization voltage is fed. The transistor T2 has a gate electrode thereof connected electrically to a second scan signal line nScan-n to which the second scan signal is fed; a drain electrode thereof connected electrically to the drain electrode of the transistor T4 and to the source electrode of the transistor T6; and a source electrode thereof connected electrically to the gate electrode of the transistor T4. The transistor T3 has a gate electrode thereof connected electrically to a first scan signal line pScan-n to which a first scan signal is fed; a source electrode thereof connected electrically to a data signal line Data to which a data signal is fed; and a drain electrode thereof connected electrically to the source electrode of the transistor T4 and to the drain electrode of the transistor T5. The transistor T4 has a gate electrode thereof connected electrically to one of two electrodes of the retention capacitor Cst and to the source electrode of the transistor T2; a source electrode thereof connected to the drain electrode of the transistor T3 and to the drain electrode of the transistor T5; and a drain electrode thereof connected electrically to the source electrode of the transistor T6. The transistor T5 has: a gate electrode thereof connected electrically to a light-emission control line EMn to which a light-emission control signal is fed; a source electrode thereof connected electrically to a high-level power supply line ELVDD to which a high-level power supply voltage is fed; and a drain electrode thereof connected electrically to the drain electrode of the transistor T3 and to the source electrode of the transistor T4. The transistor T6 has a gate electrode thereof connected electrically to the light-emission control line EMn to which the light-emission control signal is fed; a source electrode thereof connected electrically to the drain electrode of the transistor T4; and a drain electrode thereof connected electrically to the anode electrode of the light-emitting element LED. The transistor T7 has a gate electrode thereof connected electrically to the light-emission control line EMn to which the light-emission control signal is fed; a source electrode thereof connected electrically to the initialization voltage line VINI to which the initialization voltage is fed; and a drain electrode thereof connected electrically to the anode electrode of the light-emitting element LED. The other one of the two electrodes of the retention capacitor Cst is connected electrically to the high-level power supply line ELVDD to which the high-level power supply voltage is fed. The light-emitting element LED has a cathode electrode thereof connected electrically to a low-level power supply line ELVSS to which a low-level power supply voltage is fed.

A plurality of wiring lines FRL1 to FRLn crossing over the bending portion FR provided in the frame area NDA of the display device 1 as shown in FIGS. 1, 2, and 3 include: a line-break-detection wiring line FRD (detailed later); and a plurality of display wiring lines crossing over the bending portion FR. Each of a plurality of bending-portion video wiring lines, among the plurality of display wiring lines, is connected electrically to the data signal line Data of each of the plurality of pixel circuits (shown in FIG. 5) provided in the display area DA of the display device 1. In addition, the plurality of display wiring lines include, apart from the foregoing bending-portion video wiring lines: a bending-portion high-level power supply line ELVDD connected electrically to the high-level power supply line ELVDD included in each of the plurality of pixel circuits in the display area DA; and a bending-portion low-level power supply line ELVSS connected electrically to the low-level power supply line ELVSS included in each of the plurality of pixel circuits in the display area DA.

When the foregoing bending-portion video wiring lines break in a step of bending the bending portion FR as shown in FIG. 2, the data signal line Data of the corresponding pixel circuit is floated. Then, after the initialization voltage for initializing this pixel circuit is written to the gate electrode of the transistor T4 which is a drive transistor, the video voltage that should normally be written via the data signal line Data (e.g., +2 V to +7 V) is not written, and approximately the initialization voltage is retained. Since this initialization voltage is approximately from −4 V to −5 V, a large electric current flows from the source electrode to the drain electrode of the transistor T4, that is, from the high-level power supply line ELVDD side to the low-level power supply line ELVSS side. This phenomenon occurs equally in numerous pixel circuits associated with a broken data signal line Data, and a very large electric current flows in the bending-portion low-level power supply line ELVSS where each of the plurality of low-level power supply lines ELVSS included in the numerous pixel circuits associated with the broken data signal line Data merges.

Since the plurality of display wiring lines crossing over the bending portion FR, required to have a bendable shape, also inevitably have higher resistance than other areas, the bending-portion low-level power supply line ELVSS, which is most likely to be affected by a large electric current among the plurality of display wiring lines crossing over the bending portion FR, might, for example, heat up and generate smoke. These phenomena are particularly noticeable in display devices with a relatively large screen size.

In addition, if, for example, a part of the bending-portion low-level power supply line ELVSS breaks due to, for example, heating or smoke generation that might occur in the bending-portion low-level power supply line ELVSS as described above, electric current is concentrated further in the normal bending-portion low-level power supply line ELVSS, and more heat and smoke is generated.

To prevent occurrence of these issues of heating and smoke generation in the plurality of display wiring lines crossing the bending portion FR by the mechanism described above, the display device 1 in accordance with the present embodiment includes the line-break-detection wiring line FRD for detecting a break that could occur in the plurality of display wiring lines crossing over the bending portion FR.

When a display wiring line crossing over the bending portion FR breaks in the step of bending the bending portion FR of the display device 1, typically, multiple mutually adjacent display wiring lines tend to break simultaneously. Accordingly, a break in the plurality of display wiring lines crossing over the bending portion FR can be detected by providing the line-break-detection wiring line FRD which is shaped to cross over the bending portion FR at a plurality of sites. The detection method will be described later in detail.

Referring to FIGS. 1 and 3, the frame area NDA of the display device 1 includes: a terminal section TP with a plurality of terminals; the bending portion FR disposed between the terminal section TP and the display area DA; the line-break-detection wiring line FRD having an end thereof connected electrically to a first terminal in a terminal group TR1 of the terminal section TP and the other end thereof connected electrically to a second terminal PCDT′ in a terminal group TR4 of the terminal section TP; and the plurality of display wiring lines crossing over the bending portion FR. The line-break-detection wiring line FRD has such a shape as to cross over the bending portion FR at a plurality of sites at least one of which is located between two of the display wiring lines crossing over the bending portion FR.

In the display device 1 including the line-break-detection wiring line FRD, this line-break-detection wiring line FRD enables detecting a break in the display wiring lines crossing over the bending portion FR and hence enables detecting a defect of the plurality of display wiring lines crossing over the bending portion FR provided in the frame area NDA, thereby ensuring high reliability.

Referring to FIGS. 1 and 3, the plurality of wiring lines FRL1 to FRLn crossing over the bending portion FR are provided in the frame area NDA of the display device 1. In the plurality of wiring lines FRL1 to FRLn crossing over the bending portion FR, the wiring lines other than the line-break-detection wiring line FRD are the plurality of display wiring lines crossing over the bending portion FR.

In the partial enlarged view of segment X of the display device 1 in FIG. 3, for example, among the plurality of wiring lines FRLn-8 to FRLn crossing over the bending portion FR, the wiring line FRLn-6 is a portion FRD2, of the line-break-detection wiring line FRD, crossing over the bending portion FR, the wiring line FRLn is a portion PCD3′, of a peripheral-crack-detection wiring line PCD (detailed later), crossing over the bending portion FR, and the remaining wiring lines FRLn-8, FRLn-7, and FRLn-5 to FRLn-1 are the plurality of display wiring lines crossing over the bending portion FR.

In the present embodiment, as shown in FIGS. 1 and 3, the line-break-detection wiring line FRD in the display device 1 includes: first portions FRD1 each provided between the display area DA and a display-area-DA-side end part FRI of the bending portion FR; second portions FRD2 each crossing over the bending portion FR; and third portions FRD3 each provided between the terminal section TP and a terminal-section-TP-side end part FR2 of the bending portion FR. The line-break-detection wiring line FRD is described, as an example, as being located between the terminal section TP and the display area DA. Alternatively, the line-break-detection wiring line FRD may have a segment that is not located between the terminal section TP and the display area DA so long as the line-break-detection wiring line FRD has such a shape as to cross over the bending portion FR at a plurality of sites.

In the present embodiment, as shown in FIGS. 1 and 3, each of the plurality of second portions FRD2, of the line-break-detection wiring line FRD, crossing over the bending portion FR is described, as an example, as being located between two of the display wiring lines crossing over the bending portion FR to improve the probability of detecting a break in the display wiring lines crossing over the bending portion FR by using the line-break-detection wiring line FRD. This is however not the only possible implementation of the invention. Alternatively, at least one of the plurality of second portions FRD2, of the line-break-detection wiring line FRD, crossing over the bending portion FR needs only to be located between two of the display wiring lines crossing over the bending portion FR.

In the present embodiment, to detect cracks that could occur in the surroundings of the display area DA, the peripheral-crack-detection wiring line PCD located around the display area DA is described, as an example, as being provided in the frame area NDA of the display device 1 as shown in FIGS. 1 and 3, which is merely illustrative.

Referring to FIGS. 1 and 3, the peripheral-crack-detection wiring line PCD has an end thereof connected electrically to the first terminal in the terminal group TR1 of the terminal section TP and the other end thereof connected electrically to the second terminal PCDT′ in the terminal group TR4 of the terminal section TP. The line-break-detection wiring line FRD has an end thereof connected electrically to the first terminal via the peripheral-crack-detection wiring line PCD and the other end thereof connected electrically to the second terminal via the peripheral-crack-detection wiring line PCD.

Referring to FIGS. 1 and 3, the peripheral-crack-detection wiring line PCD includes: a first portion PCD1 provided around the display area DA; second portions PCD2 and PCD2′ provided between an end part of the first portion PCD1 of the peripheral-crack-detection wiring line PCD and the display-area-DA-side end part FRI of the bending portion FR; third portions PCD3 and PCD3′ crossing over the bending portion FR; and fourth portions PCD4 and PCD4′ provided between the terminal-section-TP-side end part FR2 of the bending portion FR and a particular terminal of the terminal section TP. Note that as shown in a partial enlarged view of segment Y of the display device 1 in FIG. 3, the fourth portion PCD4′, which is an end part of the peripheral-crack-detection wiring line PCD, is connected electrically to the second terminal PCDT′ in the terminal group TR4 of the terminal section TP.

In the present embodiment, the line-break-detection wiring line FRD is described, as an example, as having an end thereof connected electrically to the first terminal in the terminal group TR1 of the terminal section TP via the peripheral-crack-detection wiring line PCD and the other end thereof connected electrically to the second terminal PCDT′ in the terminal group TR4 of the terminal section TP via the peripheral-crack-detection wiring line PCD. This is however not the only possible implementation of the invention. Alternatively, the line-break-detection wiring line FRD may have an end thereof connected electrically to any one of the terminals in the terminal groups TR1, TR2, TR3, and TR4 of the terminal section TP and the other end thereof connected electrically to another one of the terminals in the terminal groups TR1, TR2, TR3, and TR4 of the terminal section TP.

As shown in FIGS. 1, 2, and 3, each terminal in the terminal groups TR1, TR2, TR3, and TR4 of the terminal section TP is connected electrically via the flexible circuit board 3 to a driver chip 4 provided on a flexible circuit board 3 and to an external substrate 5 provided on a flexible circuit board 3.

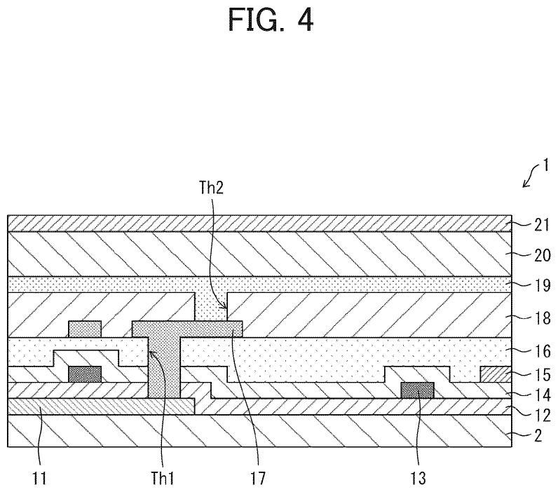

FIG. 4 is a diagram of each layer provided on the substrate 2 of the display device 1 in accordance with Embodiment 1.

Referring to FIG. 4, the display device 1 includes a semiconductor layer 11, a first insulation layer 12, a first conductive layer 13, a second insulation layer 14, a second conductive layer 15, a third insulation layer 16, a third conductive layer 17, a first organic insulation layer 18, a fourth conductive layer 19, a second organic insulation layer 20, and a fifth conductive layer 21, all of which are provided on the substrate 2 of the display device 1 in this order when viewed from the substrate 2.

The first conductive layer 13 contains formed therein the scan signal line and the gate electrode of the transistor included in the pixel circuit shown in FIG. 5. The second conductive layer 15 contains formed therein a wiring line and one of the electrodes of the retention capacitor Cst included in the pixel circuit shown in FIG. 5. The third conductive layer 17 contains formed therein the source electrode, the drain electrode, and the data signal line of the transistor included in the pixel circuit shown in FIG. 5. The fourth conductive layer 19 contains formed therein the plurality of wiring lines FRL1 to FRLn crossing over the bending portion FR. The fifth conductive layer 21 contains formed therein the anode electrode of the light-emitting element LED included in the pixel circuit shown in FIG. 5.

Referring to FIG. 4, the third conductive layer 17 is in contact with a part of the semiconductor layer 11 via a contact hole Th1. The fourth conductive layer 19 is connected electrically to the third conductive layer 17 via a contact hole Th2.

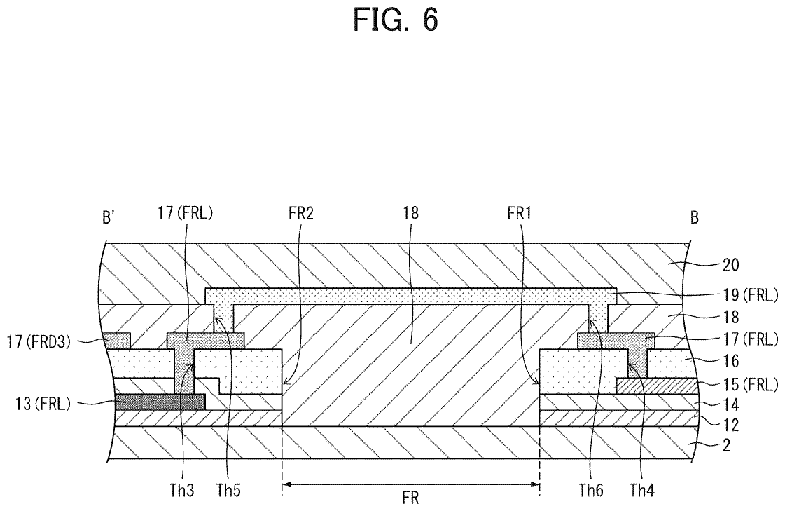

FIG. 6 is a schematic cross-sectional view of the structure of the display device 1 in accordance with Embodiment 1, taken along line B-B′ shown in FIG. 3.

Referring to FIG. 6, the bending portion FR does not include the first insulation layer 12, the second insulation layer 14, and the third insulation layer 16 formed therein, but includes the first organic insulation layer 18, the fourth conductive layer 19, and the second organic insulation layer 20 formed therein, and for this reason, is readily bent.

The wiring lines FRL crossing over the bending portion FR shown in FIG. 6 are formed by the second conductive layer 15, the third conductive layer 17, and the fourth conductive layer 19 on the display area DA side of the display-area-DA-side end part FR1 of the bending portion FR, by the fourth conductive layer 19 in the bending portion FR, and by the first conductive layer 13, the third conductive layer 17, and the fourth conductive layer 19 on the terminal section TP side of the terminal-section-TP-side end part FR2 of the bending portion FR.

Referring to FIG. 6, on the display area DA side of the display-area-DA-side end part FR1 of the bending portion FR, the third conductive layer 17 is connected electrically to the second conductive layer 15 via a contact hole Th4, and the fourth conductive layer 19 is connected electrically to the third conductive layer 17 via a contact hole Th6. In addition, on the terminal section TP side of the terminal-section-TP-side end part FR2 of the bending portion FR, the third conductive layer 17 is connected electrically to the first conductive layer 13 via a contact hole Th3, and the fourth conductive layer 19 is connected electrically to the third conductive layer 17 via a contact hole Th5.

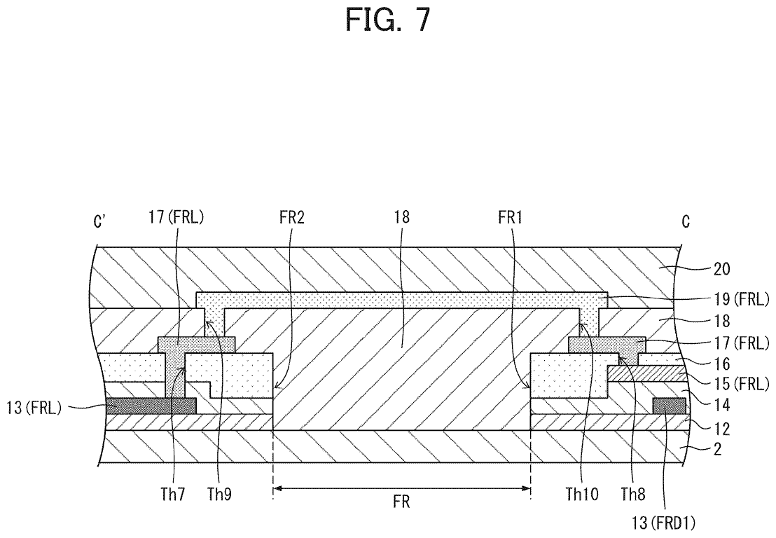

FIG. 7 is a schematic cross-sectional view of the structure of the display device 1 in accordance with Embodiment 1, taken along line C-C′ shown in FIG. 3.

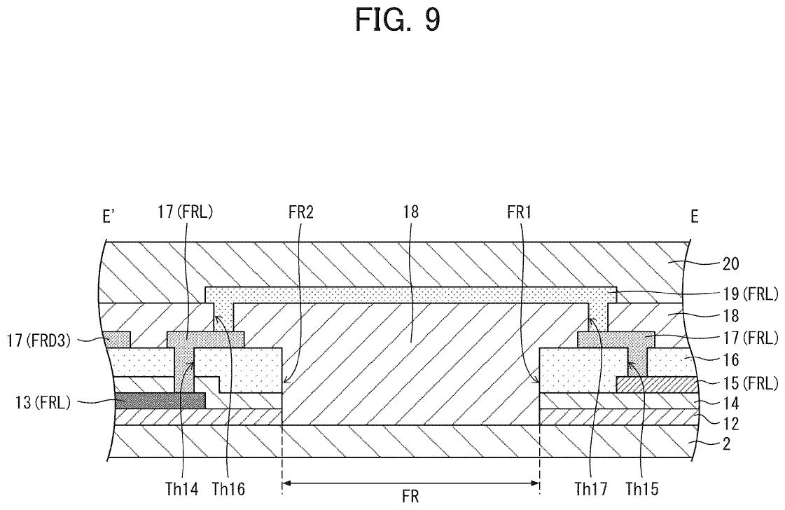

FIG. 9 is a schematic cross-sectional view of the structure of the display device 1 in accordance with Embodiment 1, taken along line E-E′ shown in FIG. 3.

The wiring lines FRL crossing over the bending portion FR shown in FIG. 7 and the wiring lines FRL crossing over the bending portion FR shown in FIG. 9 each have the same structure as the wiring lines FRL crossing over the bending portion FR shown in FIG. 6 described earlier, and description thereof is omitted here.

The wiring lines FRL crossing over the bending portion FR shown in FIG. 6, the wiring lines FRL crossing over the bending portion FR shown in FIG. 7, and the wiring lines FRL crossing over the bending portion FR shown in FIG. 9 are the plurality of display wiring lines crossing over the bending portion FR respectively and are, for example, bending-portion video wiring lines, the bending-portion high-level power supply lines ELVDD, or the bending-portion low-level power supply lines ELVSS.

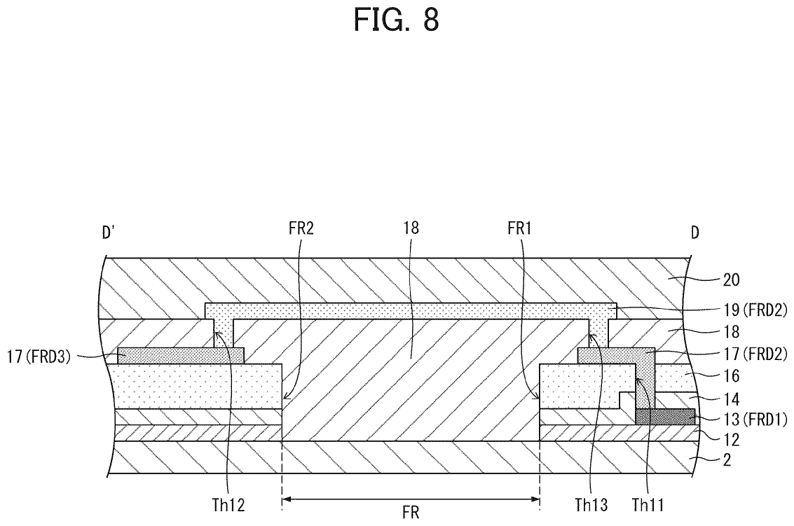

FIG. 8 is a schematic cross-sectional view of the structure of the display device 1 in accordance with Embodiment 1, taken along line D-D′ shown in FIG. 3.

The wiring lines FRL crossing over the bending portion FR shown in FIG. 8 are the line-break-detection wiring line FRD and formed by the first conductive layer 13, the third conductive layer 17, and the fourth conductive layer 19 on the display area DA side of the display-area-DA-side end part FR1 of the bending portion FR, by the fourth conductive layer 19 in the bending portion FR, and by the third conductive layer 17 and the fourth conductive layer 19 on the terminal section TP side of the terminal-section-TP-side end part FR2 of the bending portion FR.

Referring to FIG. 8, on the display area DA side of the display-area-DA-side end part FR1 of the bending portion FR, the third conductive layer 17 is connected electrically to the first conductive layer 13 via a contact hole Th11, and the fourth conductive layer 19 is connected electrically to the third conductive layer 17 via a contact hole Th13. In addition, on the terminal section TP side of the terminal-section-TP-side end part FR2 of the bending portion FR, the fourth conductive layer 19 is connected electrically to the third conductive layer 17 via a contact hole Th12.

Referring to FIG. 8, the line-break-detection wiring line FRD includes: the first portions FRD1 each located between the bending portion FR and the display area DA; the second portions FRD2 each crossing over the bending portion FR; and the third portions FRD3 each located between the bending portion FR and the terminal section TP. The second portions FRD2 of the line-break-detection wiring line FRD are formed on the first organic insulation layer 18 which is a resin layer provided in the bending portion FR.

The fourth conductive layer 19, which constitutes the second portions FRD2 of the line-break-detection wiring line FRD, preferably contains aluminum. For example, the second portions FRD2 of the line-break-detection wiring line FRD may include a stack of films of Ti, Al, and Ti. When the second portions FRD2 of the line-break-detection wiring line FRD are made of aluminum or includes a stack of films of Ti, Al, and Ti, the bending portion FR can be readily bent, which restrains wiring line breaks.

Either at least either the first portions FRD1 or the third portions FRD3 of the line-break-detection wiring line FRD preferably contain molybdenum. Since the resistance value of molybdenum is approximately an order of magnitude larger than the resistance value of aluminum, the resistance value of the line-break-detection wiring line FRD can be increased by containing molybdenum in the first portions FRD1 and the third portions FRD3, of the line-break-detection wiring line FRD, which are not bent.

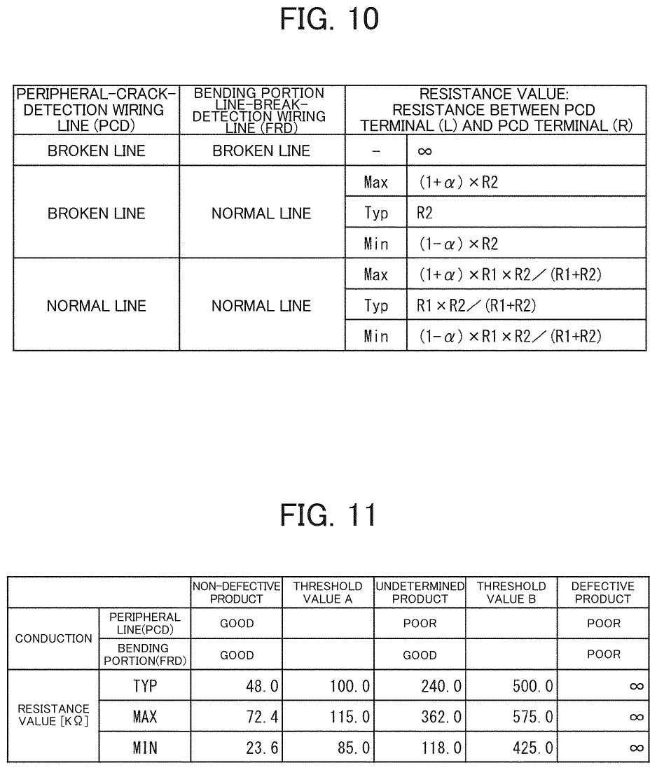

FIG. 10 is a diagram showing an example of a line-break-detection method using the peripheral-crack-detection wiring line PCD and the line-break-detection wiring line FRD provided in the display device 1 in accordance with Embodiment 1.

FIG. 11 is a diagram showing an example of a method of categorizing the display device 1 into non-defective products, undetermined products, and defective products based on the conduction state and the resistance values obtained by the line-break-detection method shown in FIG. 10.

Referring to FIGS. 1 and 3, to detect a break in the wiring by using the line-break-detection wiring line FRD and the peripheral-crack-detection wiring line PCD which are connected electrically to each other, it is necessary to specify a threshold value (boundary to determine whether the wiring is broken or normal) for the resistance value. Since the resistance value of the wiring has manufacturing variations, it is necessary to design a wiring resistance value and specify a threshold value by taking such variations into account.

As described above, by rendering the wiring line length of the line-break-detection wiring line FRD greater than the wiring line length of the peripheral-crack-detection wiring line PCD and also rendering the line-break-detection wiring line FRD having a resistance value R2 that is larger than a resistance value R1 of the peripheral-crack-detection wiring line PCD in the display device 1, specifically, by rendering the resistance value R2 greater than or equal to X times the resistance value R1 (X>1), the display device 1 can be categorized on the basis of inspection results into three categories: non-defective products, undetermined products, and defective products. X above is determined from Formula 1 below.

$$X = R 2 / R 1 = 2 α / ( 1 - α ) \qquad ( Formula 1 )$$

In the formula, α is the resistance value variation ratio of the line-break-detection wiring line FRD and the peripheral-crack-detection wiring line PCD and α>0.

The display device 1 are categorized into three categories (non-defective products, undetermined products, and defective products) as follows. The display device 1 is categorized as a non-defective product in a first case where neither the line-break-detection wiring line FRD nor the peripheral-crack-detection wiring line PCD has a break. The display device 1 is categorized as an undetermined product in a second case where only the peripheral-crack-detection wiring line PCD has a break. The display device 1 is categorized as a defective product in a third case where both the line-break-detection wiring line FRD and the peripheral-crack-detection wiring line PCD have a break.

Referring to FIG. 10, in the first case where neither the line-break-detection wiring line FRD nor the peripheral-crack-detection wiring line PCD has a break, the combined resistance value (R1×R2/(R1+R2)) of the resistance value R1 of the peripheral-crack-detection wiring line PCD and the resistance value R2 of the line-break-detection wiring line FRD is obtained as a resistance value, (1+α)×(R1×R2 /(R1+R2)) is obtained as a maximum resistance value, and (1−α)×(R1×R2/(R1+R2)) is obtained as a minimum resistance value. In the second case where only the peripheral-crack-detection wiring line PCD has a break, the resistance value R2 of the line-break-detection wiring line FRD is obtained as a resistance value, (1+α)×R2 is obtained as a maximum resistance value, and (1−α)×R2 is obtained as a minimum resistance value. In the third case where both the line-break-detection wiring line FRD and the peripheral-crack-detection wiring line PCD have a break, ∞ is obtained as a resistance value.

When the resistance value R2 of the line-break-detection wiring line FRD is smaller than the resistance value R1 of the peripheral-crack-detection wiring line PCD, the difference in resistance value is so small between the foregoing first and second cases that it becomes difficult to categorize the display device 1. In the display device 1 in accordance with the present embodiment, however, the wiring line length of the line-break-detection wiring line FRD is rendered greater than the wiring line length of the peripheral-crack-detection wiring line PCD, the resistance value R2 of the line-break-detection wiring line FRD is greater than the resistance value R1 of the peripheral-crack-detection wiring line PCD, and the combined resistance value (R1×R2 /(R1+R2)) of the resistance value R1 of the peripheral-crack-detection wiring line PCD and the resistance value R2 of the line-break-detection wiring line FRD is rendered smaller than the resistance value R2 of the line-break-detection wiring line FRD, as shown in FIGS. 1 and 3.

In addition, in the display device 1 in accordance with the present embodiment, to render the resistance value R2 of the line-break-detection wiring line FRD greater than the resistance value R1 of the peripheral-crack-detection wiring line PCD, for example, molybdenum, which has a relatively large resistance value, is used in a part of the line-break-detection wiring line FRD as described above.

Referring to FIG. 11, the display device 1 in accordance with the present embodiment is described by assuming, as an example, that the resistance value R1 of the peripheral-crack-detection wiring line PCD is 60 kΩ, the resistance value R2 of the line-break-detection wiring line FRD is 240 kΩ, the combined resistance value (R1×R2 /(R1+R2)) is 48 kΩ, and the resistance value variation ratio a of the line-break-detection wiring line FRD and the peripheral-crack-detection wiring line PCD is 0.508. Note that as to the resistance value variation ratio a of the line-break-detection wiring line FRD and the peripheral-crack-detection wiring line PCD, since the wiring resistance ratio of the line-break-detection wiring line FRD and the peripheral-crack-detection wiring line PCD had an upper limit value of 1.508, the wiring resistance ratio of the line-break-detection wiring line FRD and the peripheral-crack-detection wiring line PCD had a lower limit value of 0.492, and the intermediate value thereof was 1, 0.508, which is the difference between the upper limit value and the intermediate value and the difference between the intermediate value and the lower limit value, was taken as the resistance value variation ratio a of the line-break-detection wiring line FRD and the peripheral-crack-detection wiring line PCD.

As described above, assuming that the resistance value variation ratio α is set to 0.508, the resistance value R1 of the peripheral-crack-detection wiring line PCD is set to 60 kΩ, and the resistance value R2 of the line-break-detection wiring line FRD is set to 240 kΩ, as shown in FIG. 11, a threshold value A preferably has a minimum value (MIN) of 85.0 kΩ to ensure a judgeable resistance value difference and to restrain misjudgment when the resistance value by which the display device 1 is categorized as a non-defective product is equal to 72.4 kΩ, which is a maximum value (MAX), due to variation. Meanwhile, the threshold value A preferably has a maximum value (MAX) of 115.0 kΩ to ensure a judgeable resistance value difference and to restrain misjudgment when the resistance value by which the display device 1 is categorized as an undetermined product is equal to 118.0 kΩ, which is a minimum value (MIN), due to variation. Accordingly, in the present embodiment, 100 kΩ, which is an average value of 85.0 kΩ which is a minimum value (MIN) of the threshold value A and 115.0 kΩ which is a maximum value (MAX) of the threshold value A, is used as the threshold value A which is a categorization criterion for non-defective products and undetermined products. In addition, referring to FIG. 11, a threshold value B preferably has a minimum value (MIN) of 425.0 kΩ to ensure a judgeable resistance value difference and to restrain misjudgment when the resistance value by which the display device 1 is categorized as an undetermined product is equal to 362.0 kΩ, which is a maximum value (MAX), due to variation. Meanwhile, the threshold value B preferably has a maximum value (MAX) of 575.0 kΩ to ensure a judgeable resistance value difference and to restrain misjudgment when the resistance value by which the display device 1 is categorized as a defective product is equal to ∞ kΩ. Accordingly, in the present embodiment, 500 kΩ, which is an average value of 425.0 kΩ which is a minimum value (MIN) of the threshold value B and 575.0 kΩ which is a maximum value (MAX) of the threshold value B, is used as the threshold value B which is a categorization criterion for undetermined products and defective products.

Note that the reason for the categorization as an undetermined product is that when there occurs a break in the peripheral-crack-detection wiring line PCD, no problem entails in the display function of the display device 1 at that point in time, but reliability may be possibly affected adversely due to, for example, a crack in the display device 1. When the display device 1 is categorized as an undetermined product, the display device 1 is inspected again after passage of a prescribed time.

As described in the foregoing, according to the display device 1, the inspection using the line-break-detection wiring line FRD and the peripheral-crack-detection wiring line PCD prevents heating or smoke generation and enables categorizing the product status into 3 categories (non-defective products, undetermined products, and defective products) before succeeding steps are implemented, which enables reducing the number of inspection steps and reducing inspection target articles (e.g., only the undetermined products are subjected to additional inspection for judgement).

In other words, the display device 1 can both detect a defect in the plurality of display wiring lines crossing over the bending portion FR provided in the non-display area which is the frame area NDA and ensure high reliability.

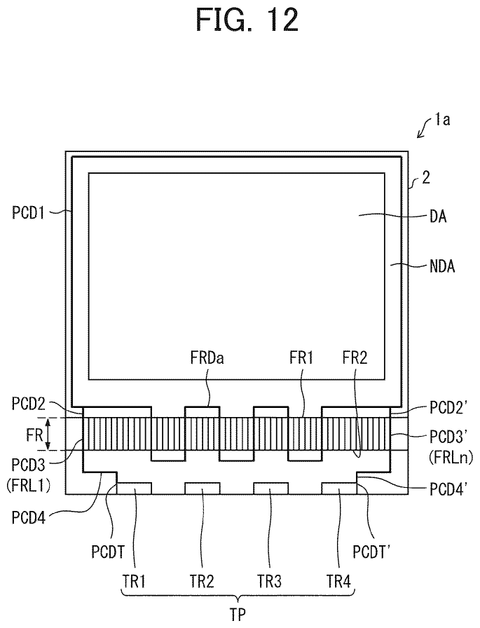

FIG. 12 is a schematic plan view of a structure of another display device la in accordance with Embodiment 1.

The display device la shown in FIG. 12 is an example where a line-break-detection wiring line FRDa is formed with a wiring line length that is shorter than the wiring line length of the line-break-detection wiring line FRD in the display device 1 shown in FIGS. 1 and 3. The wiring line length of the line-break-detection wiring line FRDa is shorter than the wiring line length of the peripheral-crack-detection wiring line PCD, and the resistance value R1 of the peripheral-crack-detection wiring line PCD is greater than the resistance value R2 of the line-break-detection wiring line FRDa.

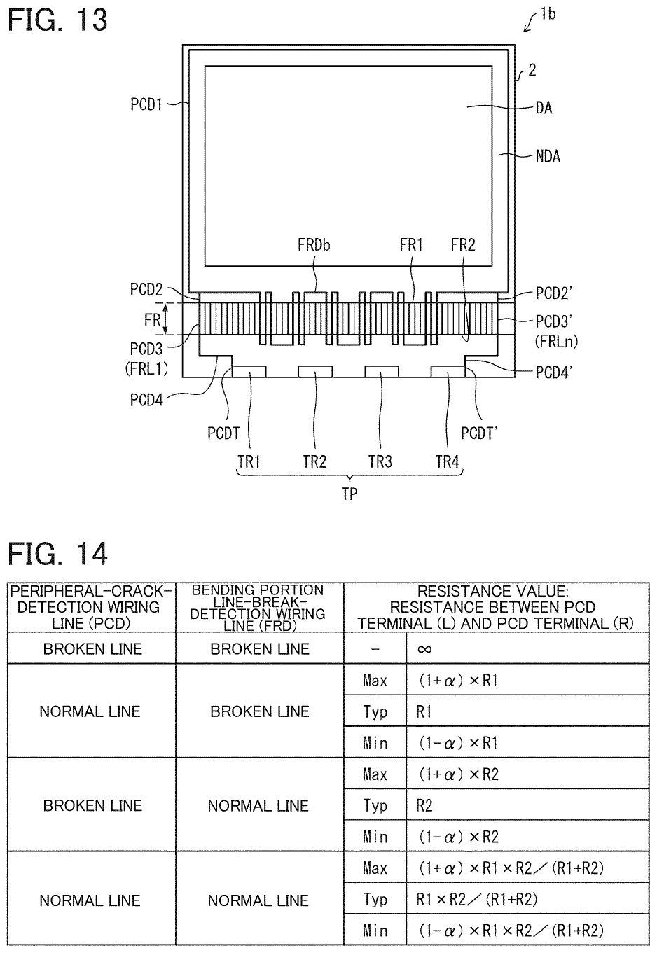

FIG. 13 is a schematic plan view of a structure of yet another display device 1b in accordance with Embodiment 1.

The display device 1b shown in FIG. 13 is an example where a line-break-detection wiring line FRDb is formed with a wiring line length that is even longer than the wiring line length of the line-break-detection wiring line FRD in the display device 1 shown in FIGS. 1 and 3.

FIG. 14 is a diagram showing another example of a line-break-detection method using the peripheral-crack-detection wiring line PCD and the line-break-detection wiring line FRDa provided in the display device la in accordance with Embodiment 1 shown in FIG. 12.

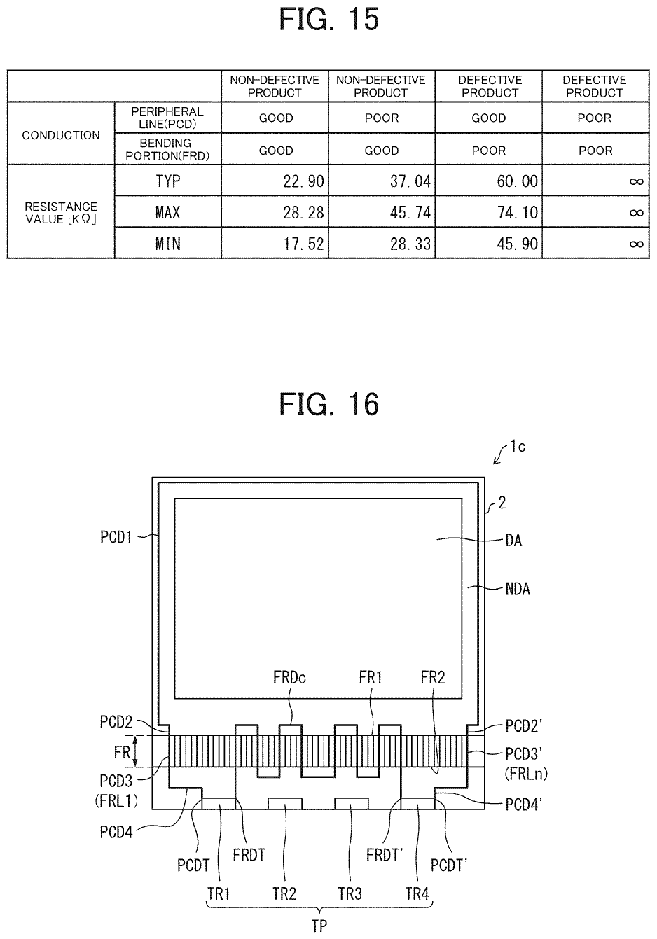

FIG. 15 is a diagram showing an example of a method of categorizing display devices into non-defective products, undetermined products, and defective products based on the conduction state and the resistance values obtained by the line-break-detection method shown in FIG. 14.

Referring to FIGS. 14 and 15, here, a description is given by taking, as an example, categorization in which the display device 1 is categorized as a non-defective product in a first case where neither the line-break-detection wiring line FRDa nor the peripheral-crack-detection wiring line PCD has a break, as a non-defective product in a second case where only the peripheral-crack-detection wiring line PCD has a break, as a defective product in a third case where the line-break-detection wiring line FRDa has a break, but the peripheral-crack-detection wiring line PCD has no break, and as a defective product in a fourth case where both the line-break-detection wiring line FRDa and the peripheral-crack-detection wiring line PCD have a break.

Referring to FIG. 14, in the first case where neither the line-break-detection wiring line FRDa nor the peripheral-crack-detection wiring line PCD has a break, the combined resistance value (R1×R2/(R1+R2)) of the resistance value R1 of the peripheral-crack-detection wiring line PCD and the resistance value R2 of the line-break-detection wiring line FRDa is obtained as a resistance value, (1+α)×(R1×R2/(R1+R2)) is obtained as a maximum resistance value, and (1−α)×(R1×R2/(R1+R2)) is obtained as a minimum resistance value. In the second case where only the peripheral-crack-detection wiring line PCD has a break, the resistance value R2 of the line-break-detection wiring line FRD is obtained as a resistance value, (1+α)×R2 is obtained as a maximum resistance value, and (1−α)×R2 is obtained as a minimum resistance value. In the third case where the line-break-detection wiring lines FRD, FRDa, and FRDb have a break, but the peripheral-crack-detection wiring line PCD has no break, the resistance value R1 of the line-break-detection wiring line FRD is obtained as a resistance value, (1+α)×R1 is obtained as a maximum resistance value, and (1−α)×R1 is obtained as a minimum resistance value. In the fourth case where both the line-break-detection wiring line FRDa and the peripheral-crack-detection wiring line PCD have a break, o is obtained as a resistance value.

Referring to FIG. 15, here, a description is given by assuming, as an example, that the resistance value R1 of the peripheral-crack-detection wiring line PCD is 60 kΩ, the resistance value R2 of the line-break-detection wiring line FRDa is 37 kΩ, the combined resistance value (R1×R2/(R1+R2)) is 22.9 k≤2, and the resistance value variation ratio a of the line-break-detection wiring line FRDa and the peripheral-crack-detection wiring line PCD is 0.235.

In addition, here, a description has been given by assuming, as an example, categorization in which the display device 1 is categorized as a defective product in the third case where the line-break-detection wiring line FRDa has a break, but the peripheral-crack-detection wiring line PCD has no break. As described above, however, the display device 1 may be categorized as an undetermined product and then inspected again after passage of a prescribed time.

As described in the foregoing, in the display device la, the resistance value R1 of the peripheral-crack-detection wiring line PCD is greater than the resistance value R2 of the line-break-detection wiring line FRDa, and the resistance value R2 of the line-break-detection wiring line FRDa is greater than the combined resistance value (R1×R2/(R1+R2)) of the resistance value R1 of the peripheral-crack-detection wiring line PCD and the resistance value R2 of the line-break-detection wiring line FRDa.

### Embodiment 2

A description is given next of Embodiment 2 of the present invention with reference to FIG. 16. A display device 1c in accordance with the present embodiment differs from foregoing Embodiment 1 in that the peripheral-crack-detection wiring line PCD and a line-break-detection wiring line FRDc are not electrically connected. The display device 1c has otherwise the same structure as in Embodiment 1 described above. For convenience of description, members of the present embodiment that have the same function as members shown in the drawings for Embodiment 1 are denoted by the same reference numerals, and description thereof is omitted.

FIG. 16 is a schematic plan view of a structure of the display device 1c in accordance with Embodiment 2.

Referring to FIG. 16, in the display device 1c, the peripheral-crack-detection wiring line PCD and the line-break-detection wiring line FRDc are not electrically connected, the line-break-detection wiring line FRDc has an end thereof connected electrically to a first terminal of the terminal section TP and the other end thereof connected electrically to a second terminal of the terminal section TP, and the peripheral-crack-detection wiring line PCD has an end thereof connected electrically to a third terminal of the terminal section TP and the other end thereof connected electrically to a fourth terminal of the terminal section TP.

The display device 1c can inspect peripheral crack detection and wiring break detection of the bending portion FR by using separate wiring lines, and the display device 1c can both detect a defect in the plurality of display wiring lines crossing over the bending portion FR provided in the non-display area which is the frame area NDA and ensure high reliability.

### Embodiment 3

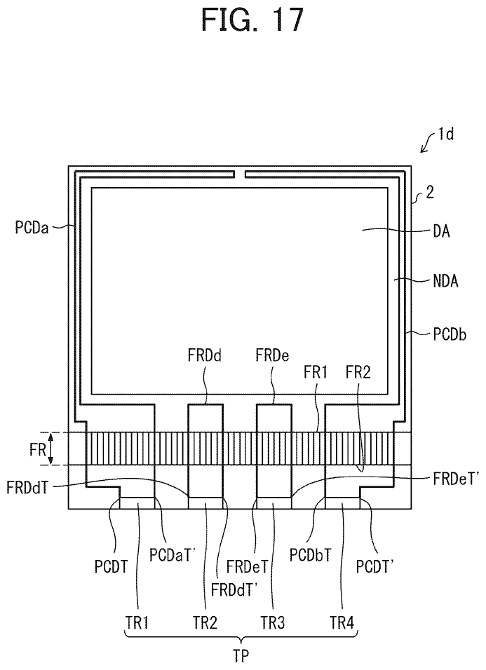

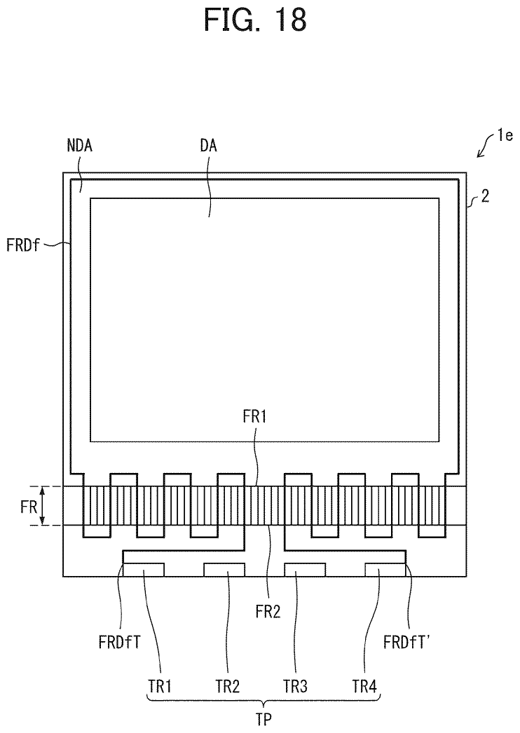

A description is given next of Embodiment 3 of the present invention with reference to FIG. 17. A display device 1d in accordance with the present embodiment differs from foregoing Embodiments 1 and 2 in that there are provided two peripheral-crack-detection wiring lines PCDa and PCDb and two line-break-detection wiring lines FRDd and FRDe. The display device 1d has otherwise the same structure as in Embodiments 1 and 2 described above. For convenience of description, members of the present embodiment that have the same function as members shown in the drawings for Embodiments 1 and 2 are denoted by the same reference numerals, and description thereof is omitted.

FIG. 17 is a schematic plan view of a structure of the display device 1d in accordance with Embodiment 3.

Referring to FIG. 17, the display device 1d includes the two peripheral-crack-detection wiring lines PCDa and PCDb and the two line-break-detection wiring lines FRDd and FRDe. The peripheral-crack-detection wiring line PCDa has an end thereof connected electrically to the first terminal of the terminal section TP and the other end thereof connected electrically to the second terminal of the terminal section TP, the line-break-detection wiring line FRDd has an end thereof connected electrically to the third terminal of the terminal section TP and the other end thereof connected electrically to the fourth terminal of the terminal section TP, the line-break-detection wiring line FRDe has an end thereof connected electrically to a fifth terminal of the terminal section TP and the other end thereof connected electrically to a sixth terminal of the terminal section TP, and the peripheral-crack-detection wiring line PCDb has an end thereof connected electrically to a seventh terminal of the terminal section TP and the other end thereof connected electrically to an eighth terminal of the terminal section TP.

The display device 1d can both perform peripheral crack detection by using two separately provided wiring lines and perform wiring break detection in the bending portion FR also by using two separately provided wiring lines, and the display device 1d can both detect a defect in the plurality of display wiring lines crossing over the bending portion FR provided in the non-display area which is the frame area NDA and ensure high reliability.

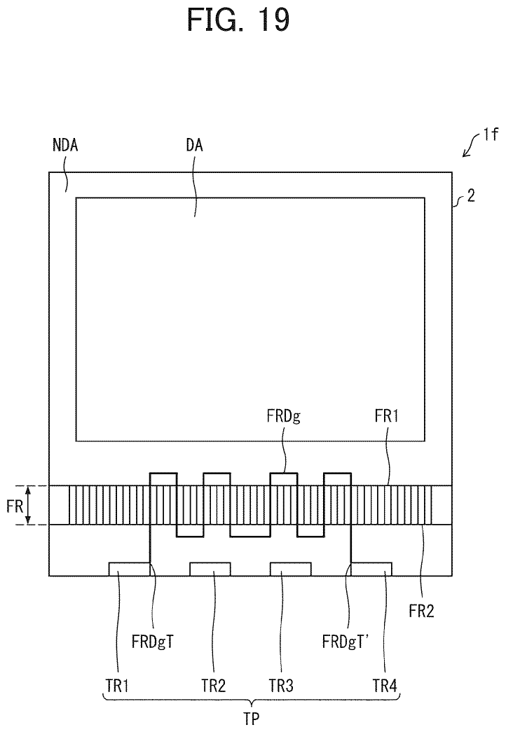

Embodiment 4 A description is given next of Embodiment 2 of the present invention with reference to FIG. 18. A display device 1e in accordance with the present embodiment differs from foregoing Embodiments 1 to 3 in that a line-break-detection wiring line FRDf includes a peripheral-crack-detection wiring line located around the display area DA. The display device 1e has otherwise the same structure as in Embodiments 1 to 3 described above. For convenience of description, members of the present embodiment that have the same function as members shown in the drawings for Embodiments 1 to 3 are denoted by the same reference numerals, and description thereof is omitted.

FIG. 18 is a schematic plan view of a structure of the display device 1e in accordance with Embodiment 4.

Referring to FIG. 18, in the display device 1e, the line-break-detection wiring line FRDf includes a peripheral-crack-detection wiring line located around the display area DA, and the line-break-detection wiring line FRDf has an end thereof connected to the first terminal of the terminal section TP and the other end thereof connected to the second terminal of the terminal section TP.

The display device 1e allows for categorization into two categories: non-defective products and defective products. The display device 1e can both detect a defect in the plurality of display wiring lines crossing over the bending portion FR provided in the non-display area which is the frame area NDA and ensure high reliability.

### Embodiment 5

A description is given next of Embodiment 5 of the present invention with reference to FIG. 19. A display device 1f in accordance with the present embodiment differs from foregoing Embodiments 1 to 4 in that there is provided no peripheral-crack-detection wiring line. The display device 1f has otherwise the same structure as in Embodiments 1 to 4. For convenience of description, members of the present embodiment that have the same function as members shown in the drawings for Embodiments 1 to 4 are denoted by the same reference numerals, and description thereof is omitted.

FIG. 19 is a schematic plan view of a structure of the display device 1f in accordance with Embodiment 5.

Referring to FIG. 19, in the display device 1f, there is provided no peripheral-crack-detection wiring line. A line-break-detection wiring line FRDg has an end thereof connected to a first terminal FRDgT of the terminal section TP, and the line-break-detection wiring line FRDg has the other end thereof connected to a second terminal FRDgT′ of the terminal section TP.

The display device 1f allows for categorization into two categories: non-defective products and defective products. The display device 1f can both detect a defect in the plurality of display wiring lines crossing over the bending portion FR provided in the non-display area which is the frame area NDA and ensure high reliability.

### ADDITIONAL REMARKS

The present invention is not limited to the description of the embodiments above and may be altered within the scope of the claims. Embodiments based on a proper combination of technical means disclosed in different embodiments are encompassed in the technical scope of the present invention. Furthermore, new technical features can be created by combining different technical means disclosed in the embodiments.

### INDUSTRIAL APPLICABILITY

The present invention is applicable to display devices.

1-16. (canceled)

17. A display device comprising: a display area including a subpixel;
and a frame area surrounding the display area, wherein the frame area includes:
a terminal section including a plurality of terminals;
a bending portion located between the terminal section and the display area;
a line-break-detection wiring line having an end connected electrically to a first terminal of the terminal section and another end connected electrically to a second terminal of the terminal section; and
a plurality of display wiring lines,
the line-break-detection wiring line is shaped so as to cross over the bending portion at a plurality of sites,
at least one of the plurality of sites is located between two of the plurality of display wiring lines crossing over the bending portion, and
each of the plurality of sites is located between two of the plurality of display wiring lines crossing over the bending portion.

18. The display device according to claim 17, wherein the line-break-detection wiring line is located between the terminal section and the display area.

19. The display device according to claim 17, wherein
the frame area includes a peripheral-crack-detection wiring line located around the display area,
the peripheral-crack-detection wiring line has an end connected to the first terminal,
the peripheral-crack-detection wiring line has another end connected to the second terminal,
the line-break-detection wiring line has an end connected electrically to the first terminal via the peripheral-crack-detection wiring line, and
the line-break-detection wiring line has another end connected electrically to the second terminal via the peripheral-crack-detection wiring line.

20. The display device according to claim 17, wherein
the frame area includes a peripheral-crack-detection wiring line located around the display area,
the peripheral-crack-detection wiring line has an end connected electrically to a third terminal of the terminal section, and
the peripheral-crack-detection wiring line has another end connected electrically to a fourth terminal of the terminal section.

21. The display device according to claim 17, wherein the frame area includes another line-break-detection wiring line that is formed between the terminal section and the display area so as to cross over the bending portion at a plurality of sites and that has an end connected electrically to a third terminal of the terminal section and another end connected electrically to a fourth terminal of the terminal section.

22. A display device comprising: a display area including a subpixel; and a frame area surrounding the display area, wherein
the frame area includes:
a terminal section including a plurality of terminals;
a bending portion located between the terminal section and the display area;
a line-break-detection wiring line having an end connected electrically to a first terminal of the terminal section and another end connected electrically to a second terminal of the terminal section; and
plurality of display wiring lines,
the line-break-detection wiring line is shaped so as to cross over the bending portion at a plurality of sites,
at least one of the plurality of sites is located between two of the plurality of display wiring lines crossing over the bending portion,
the line-break-detection wiring line has an end connected to the first terminal,
the line-break-detection wiring line has another end connected to the second terminal, and
the line-break-detection wiring line includes a peripheral-crack-detection wiring line located around the display area.

23. The display device according to claim 19, wherein the line-break-detection wiring line has a greater wiring line length than does the peripheral-crack-detection wiring line.

24. The display device according to claim 19, wherein a combined resistance value (R1×R2/(R1+R2)) of a resistance value R1 of the peripheral-crack-detection wiring line and a resistance value R2 of the line-break-detection wiring line is smaller than the resistance value R2 of the line-break-detection wiring line.

25. The display device according to claim 19, wherein
a resistance value R1 of the peripheral-crack-detection wiring line is greater than a resistance value R2 of the line-break-detection wiring line, and
the resistance value R2 of the line-break-detection wiring line is greater than a combined resistance value (R1×R2/(R1+R2)) of the resistance value R1 of the peripheral-crack-detection wiring line and the resistance value R2 of the line-break-detection wiring line.

26. The display device according to claim 17, wherein the line-break-detection wiring line includes: a first portion located between the bending portion and the display area; a second portion crossing over the bending portion; and a third portion located between the bending portion and the terminal section.

27. The display device according to claim 26, wherein the second portion contains aluminum.

28. The display device according to claim 27, wherein the second portion includes a stack of films of Ti, Al, and Ti.

29. The display device according to claim 26, wherein either one or both of the first portion and the third portion contain(s) molybdenum.

30. The display device according to claim 26, wherein the second portion is formed on a resin layer provided in the bending portion.

31. The display device according to claim 17, wherein the subpixel includes a light-emitting element, and the light-emitting element includes either a light-emitting layer containing quantum dots or an organic light-emitting layer.

32. A display device comprising: a display area including a subpixel; and a frame area surrounding the display area, wherein
the frame area includes:
a terminal section including a plurality of terminals;
a bending portion located between the terminal section and the display area;
a line-break-detection wiring line having an end connected electrically to a first terminal of the terminal section and another end connected electrically to a second terminal of the terminal section; and
a plurality of display wiring lines,
the line-break-detection wiring line is shaped so as to cross over the bending portion at a plurality of sites,
at least one of the plurality of sites is located between two of the plurality of display wiring lines crossing over the bending portion,
the frame area includes a peripheral-crack-detection wiring line located around the display area,
the peripheral-crack-detection wiring line has an end connected to the first terminal,
the peripheral-crack-detection wiring line has another end connected to the second terminal,
the line-break-detection wiring line has an end connected electrically to the first terminal via the peripheral-crack-detection wiring line, and
the line-break-detection wiring line has another end connected electrically to the second terminal via the peripheral-crack-detection wiring line.

33. The display device according to claim 32, wherein the line-break-detection wiring line has a greater wiring line length than does the peripheral-crack-detection wiring line.

34. The display device according to claim 32, wherein a combined resistance value (R1×R2/(R1+R2)) of a resistance value R1 of the peripheral-crack-detection wiring line and a resistance value R2 of the line-break-detection wiring line is smaller than the resistance value R2 of the line-break-detection wiring line.

35. The display device according to claim 32, wherein
a resistance value R1 of the peripheral-crack-detection wiring line is greater than a resistance value R2 of the line-break-detection wiring line, and
the resistance value R2 of the line-break-detection wiring line is greater than a combined resistance value (R1×R2/(R1+R2)) of the resistance value R1 of the peripheral-crack-detection wiring line and the resistance value R2 of the line-break-detection wiring line.
